(19) United States
(12) Patent Application Publication
(10) Pub. No.: US 2021/0287887 A1
(43) Pub. Date: Sep. 16, 2021

(54) PLASMA MEASURING APPARATUS AND PLASMA MEASURING METHOD

(71) Applicant: TOKYO ELECTRON LIMITED, Tokyo (JP)

(72) Inventor: Shinji KUBOTA, Miyagi (JP)

(73) Assignee: TOKYO ELECTRON LIMITED, Tokyo (JP)

(21) Appl. No.: 17/186,140

(22) Filed: Feb. 26, 2021

(30) Foreign Application Priority Data
Mar. 11, 2020 (JP) 2020-041977

(51) Int. Cl. H01J 37/32

(52) U.S. Cl. CPC H01J 37/32972; H01J 37/32082; H01J 2237/24585; H01J 2237/0492; H01J 37/32449

(57) ABSTRACT

A plasma measuring apparatus includes: a chamber; a stage provided inside the chamber; a plasma generation source configured to generate plasma in the chamber; an inorganic electroluminescence (EL) substrate placed on the stage and configured to emit light when an electric field is applied; a transmission window provided in the chamber and configured to transmit light; a spectroscope disposed outside the chamber and configured to measure a light emission of the inorganic EL substrate through the transmission window; and a controller configured to measure an ion energy from a result of the measurement by the spectroscope.

### CROSS-REFERENCE TO RELATED APPLICATIONS

This application is based on and claims priority from Japanese Patent Application No. 2020-041977, filed on Mar. 11, 2020, with the Japan Patent Office, the disclosure of which is incorporated herein in its entirety by reference.

### TECHNICAL FIELD

The present disclosure relates to a plasma measuring apparatus and a plasma measuring method.

### BACKGROUND

Japanese Patent Laid-Open Publication No. 2014-513390 discloses a method of measuring the ion current using a measurement substrate as an ion energy measuring method.

### SUMMARY

According to an aspect of the present disclosure, a plasma measuring apparatus includes a chamber, a stage; a plasma generation source, an inorganic EL substrate, a transmission window, a spectroscope, and a controller. The stage is provided inside the chamber. The plasma generation source generates plasma in the chamber. The inorganic EL substrate is placed on the stage, and emits light when an electric field is applied. The transmission window is provided in the chamber, and transmits light. The spectroscope is disposed outside the chamber, and measures a light emission of the inorganic EL substrate through the transmission window. The controller measures ion energy from a result of the measurement by the spectroscope.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a plasma processing apparatus according to an embodiment.

FIG. 2 is a schematic cross-sectional view illustrating an example of a configuration of an inorganic electroluminescence (EL) substrate according to an embodiment.

FIG. 3 is a view schematically illustrating an electrical state of the surface of a substrate when the substrate is etched, according to an embodiment.

FIG. 4 is a view illustrating an example of a relationship between the light emission intensity of a light emitting layer and the electric field intensity according to an embodiment.

FIG. 5 is a view illustrating an example of the distribution of ion energy according to an embodiment.

FIG. 6 is a flowchart illustrating an example of the flow of a plasma measuring method according to an embodiment.

FIG. 7 is a view illustrating an example of the measured light emission intensity according to an embodiment.

FIG. 8 is a flowchart illustrating an example of a process other than the flow of the plasma measuring method according to an embodiment.

FIG. 9 is a schematic cross-sectional view illustrating another example of the configuration of the inorganic EL substrate according to an embodiment.

FIG. 10 is a schematic cross-sectional view illustrating yet another example of the configuration of the inorganic EL substrate according to an embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments of a plasma measuring apparatus and a plasma measuring method according to the present disclosure will be described in detail with reference to the drawings. The plasma measuring apparatus and the plasma measuring method of the present disclosure are not limited to the embodiments.

When the ion energy in a plasma processing space is measured using a measurement substrate, wires are required to connect the measurement substrate inside the plasma processing space (inside a chamber) and a voltmeter/an ammeter outside the plasma processing space (outside the chamber) to each other. Since a radio-frequency power applied for generating plasma may leak to the outside and cause a malfunction in other systems, the wires need to extract only the direct current through a low-pass filter. However, it may be difficult to thoroughly remove the radio-frequency current through the low-pass filter, and the radio-frequency current may flow from the substrate to the GND, which may cause an error in measurement. Further, since the potential on the measurement substrate may reach several KV, the wires need to take a pressure resistance with the GND. However, it is very difficult to make the wires having the high pressure resistance of several KV. Thus, when the measurement according to this measuring method is performed under the high bias condition as used in an actual process, the wires may have no pressure resistance, and an insulation breakdown may occur, thereby causing an abnormal discharge. Further, the measurement system may be destroyed due to the abnormal discharge. Thus, it has been difficult to measure the ion energy within the high power area.

Accordingly, a new technique of measuring the ion energy of a plasma processing is expected.

### EMBODIMENTS

### Configuration of Apparatus

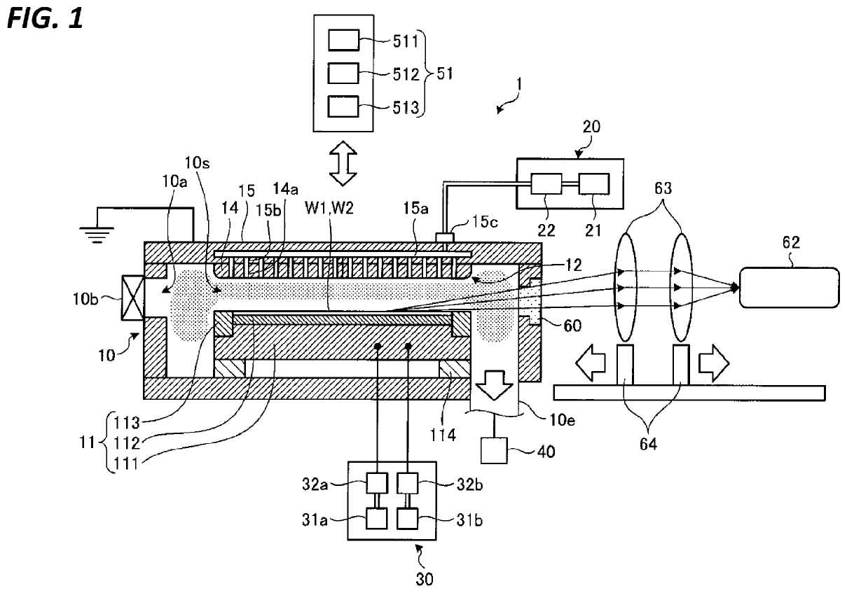

Embodiments will be described. Hereinafter, descriptions will be made on a case where the configuration of the plasma measuring apparatus of the present disclosure is applied to a plasma processing apparatus. FIG. 1 is a schematic cross-sectional view illustrating an example of a plasma processing apparatus 1 according to an embodiment. The plasma processing apparatus 1 according to the embodiment is, for example, a capacitively coupled plasma (CCP) type plasma etching apparatus that includes parallel-flat-plate electrodes. The plasma processing apparatus 1 includes a plasma processing chamber 10, a gas supply 20, a radio-frequency (RF) power supply 30, and an exhaust system 40. The plasma processing apparatus 1 further includes a support 11 and an upper-electrode shower head 12. The plasma processing apparatus 1 further includes a controller 51.

The plasma processing chamber 10 is made of a material such as, for example, aluminum, and formed in, for example, a substantially cylindrical shape. The inner wall surface of the plasma processing chamber 10 is anodized. The plasma processing chamber 10 is grounded for safety. The support 11 is disposed at a lower area of the plasma processing space 10s inside the plasma processing chamber 10. The upper-electrode shower head 12 is disposed above the support 11, and may function as a portion of the ceiling of the plasma processing chamber 10.

The support 11 is configured to support a substrate W1 in the plasma processing space 10s. In an embodiment, the support 11 includes a lower electrode 111, an electrostatic chuck 112, and an edge ring 113. The electrostatic chuck 112 is disposed on the lower electrode 111, and configured to support the substrate W1 on the upper surface thereof. The edge ring 113 is disposed to surround the substrate W1 on the upper surface of the peripheral edge of the lower electrode 111. Although not illustrated, in an embodiment, the support 11 may include a temperature control module configured to adjust at least one of the electrostatic chuck 112 and the substrate W1 to a target temperature. The temperature control module may include a heater, a flow path, or a combination thereof. A temperature control fluid such as a refrigerant or a heat transfer gas flows through the flow path. The support 11 is supported by a support member 114 provided on the bottom surface of the plasma processing chamber 10. The support member 114 is made of an insulating material. The plasma processing chamber 10 and the support 11 are insulated by the support member 114.

The upper-electrode shower head 12 is supported on the top of the plasma processing chamber 10 via an insulating shielding member (not illustrated). The upper-electrode shower head 12 includes an electrode plate 14 and an electrode support 15. The lower surface of the electrode plate 14 faces the plasma processing space 10s. A plurality of gas injection ports 14a is formed in the electrode plate 14. The electrode plate 14 is made of a material including, for example, silicon.

The electrode support 15 is made of, for example, a conductive material such as aluminum. The electrode support 15 supports the electrode plate 14 to be freely detachable from above. The electrode support 15 is grounded for safety. The electrode support 15 may have a water-cooled structure (not illustrated). A diffusion chamber 15a is formed inside the electrode support 15. A plurality of gas flow ports 15b extends downward (toward the support 11) from the diffusion chamber 15a to communicate with the gas injection ports 14a of the electrode plate 14. The electrode support 15 is provided with a gas inlet 15c that introduces a processing gas into the diffusion chamber 15a, and the gas supply 20 is connected to the gas inlet 15c via a pipe.

The upper-electrode shower head 12 is configured to supply one or more processing gases from the gas supply 20 into the plasma processing space 10s. In an embodiment, the upper-electrode shower head 12 is configured to supply one or more processing gases from the gas inlet 15c into the plasma processing space 10s through the gas diffusion chamber 12b, the gas outlet 12c, and the gas injection ports 14a.

The gas supply 20 may include one or more gas sources 21 and one or more flow rate controllers 22. In an embodiment, the gas supply 20 is configured to supply one or more processing gases from their corresponding gas sources 21 to the gas inlet 15c through their corresponding flow rate controllers 22. Each flow rate controller 22 may include, for example, a mass flow controller or a pressure-controlled flow rate controller. Further, the gas supply 20 may include one or more flow rate modulation devices that modulate or pulse the flow rates of one or more processing gases.

The RF power supply 30 is configured to supply an RF power, for example, one or more RF signals, to one or more electrodes such as the lower electrode 111, the upper-electrode shower head 12, or both the lower electrode 111 and the upper-electrode shower head 12. As a result, plasma is generated from one or more processing gases supplied into the plasma processing space 10s. Accordingly, the RF power supply 30 may function as at least a portion of a plasma generator configured to generate plasma from one or more processing gases in the plasma processing chamber 10. In an embodiment, the RF power supply 30 includes two RF generators 31a and 31b and two matching circuits 32a and 32b. In an embodiment, the RF power supply 30 is configured to supply a first RF signal from the RF generator 31a to the lower electrode 111 via the first matching circuit 32a. For example, the first RF signal may have a frequency in the range of 27 MHz to 100 MHz.

In an embodiment, the RF power supply 30 is configured to supply a second RF signal from the RF generator 31b to the lower electrode 111 via the second matching circuit 32b. For example, the second RF signal may have a frequency in the range of 400 kHz to 13.56 MHz. Instead of the second RF generator 31b, a direct current (DC) pulse generator may be used.

Although not illustrated, other embodiments of the present disclosure may be considered. For example, the RF power supply 30 may be configured to supply a first RF signal from an RF generator to the lower electrode 111, supply a second RF signal from another RF generator to the lower electrode 111, and supply a third RF signal from yet another RF generator to the lower electrode 111. In another alternative embodiment, a DC voltage may be applied to the upper-electrode shower head 12.

In various embodiments, the amplitudes of one or more RF signals (i.e., the first RF signal, the second RF signal and others) may be pulsed or modulated. The amplitude modulation may include pulsing the amplitudes of the RF signals between an ON state and an OFF state or between two or more different ON states.

The exhaust system 40 may be connected to an exhaust port 10e provided, for example, at the bottom of the plasma processing chamber 10. The exhaust system 40 may include a pressure valve and a vacuum pump. The vacuum pump may include a turbo molecular pump, a roughing vacuum pump, or a combination thereof.

An opening 10a is provided in the side wall of the plasma processing chamber 10 to carry the substrate W1 into/out from the plasma processing chamber 10. The opening 10a is openable/closable by a gate valve 10b.

A transmission window 60 is provided in the side surface of the plasma processing chamber 10 to transmit light. In the present embodiment, the transmission window 60 is provided in the side surface of the plasma processing chamber 10 opposite to the opening 10a. The transmission window 60 is configured by, for example, a quartz substrate, and has a transmitting property to transmit light (visible light).

When a measurement is performed, an inorganic EL substrate W2 is placed on the support 11, instead of the substrate W. The inorganic EL substrate W2 is formed in the same size as that of the substrate W1, and emits light when an electric field is applied.

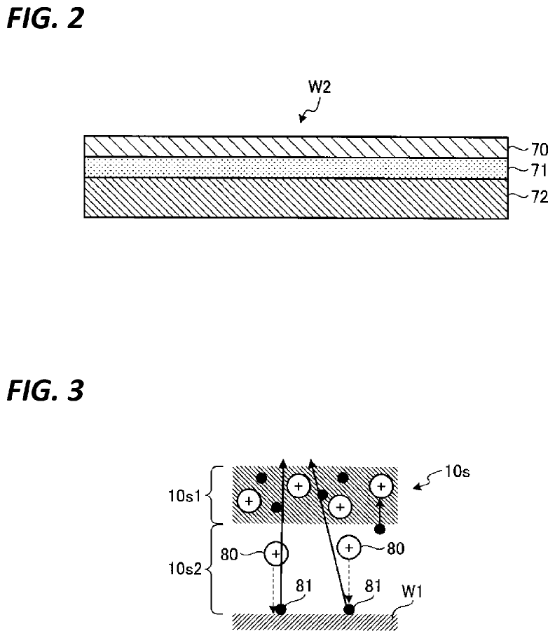

FIG. 2 is a schematic cross-sectional view illustrating an example of the configuration of the inorganic EL substrate W2 according to the embodiment. FIG. 2 represents an example of the inorganic EL substrate W2. In FIG. 2, the upper side is close to the upper-electrode shower head 12, and the lower side is close to the support 11. The inorganic EL substrate W2 includes a dielectric layer 70, a light emitting layer 71, and a silicon substrate 72 that supports the dielectric layer 70 and the light emitting layer 71. In the inorganic EL substrate W2, the light emitting layer 71 is stacked on the silicon substrate 72, and the dielectric layer 70 is stacked on the light emitting layer 71. The silicon substrate 72 is, for example, 12 inches (300 mm) in diameter and 775 um in thickness. The light emitting layer 71 is formed on the entire upper surface of the silicon substrate 72 by a phosphor, and has a thickness of tens of nm (e.g., 60 nm). The phosphor of the light emitting layer 71 may be a material of which light emission intensity changes according to the electric field intensity. Examples of the phosphor of the light emitting layer 71 may include SrS:Ce, ZnS:Tm, ZnS:Mo, SnS:Tm, SnS:Sm, CaS:Eu, and CaS:Se. In each material enumerated as the phosphor, the left side of the semicolon “:” represents the main material of the phosphor, and the right side thereof represents a small amount of material added in an amount of, for example, 1% or less. For example, in SrS:Ce, SrS is the main material, and Ce is a material added in an amount of 1% or less. The dielectric layer 70 is formed on the entire upper surface of the silicon substrate 72 by a dielectric, and has a thickness of hundreds of nm (e.g., 650 nm). Examples of the dielectric may include SiO₂, SiN, Y₂O₃, Al₂O₃, and Ta₂O₅.

In the inorganic EL substrate W2, the light emitting layer 71 emits light when an electric field is applied.

Descriptions will be made referring back to FIG. 1. A spectroscope 62 is disposed outside the transmission window 60 of the plasma processing chamber 10. A plurality of lenses 63 is provided between the spectroscope 62 and the transmission window 60. The plurality of lenses 63 are arranged to focus on a portion of the light emitting area of the inorganic EL substrate W2. The plurality of lenses 63 are movable by a driving mechanism 64. The driving mechanism 64 includes an actuator such as a motor and a power transmission component such as a gear or a rod, and moves each of the plurality of lenses 63 under the control of the controller 51. The plurality of lenses 63 are moved by the driving mechanism 64, so that the position of the focal point may move within the light emitting area of the inorganic EL substrate W2. The driving mechanism 64 may drive both the lenses 63 and the spectroscope 62 or drive only the spectroscope 62 to move the position of the focal point within the light emitting area of the inorganic EL substrate W2.

The spectroscope 62 measures the wavelength and the emission intensity of the light emitted by the inorganic EL substrate W2 in the area on which the plurality of lenses 63 focus. The driving mechanism 64 moves the plurality of lenses 63 to move the position of the focal point within the light emitting area of the inorganic EL substrate W2, so that the spectroscope 62 may measure the light emission of each light emitting area of the inorganic EL substrate W2. The spectroscope 62 outputs measurement data of the measured wavelength and light emission intensity to the controller 51.

The controller 51 processes computer-executable instructions to cause the plasma processing apparatus 1 to perform various processes to be described in the present disclosure. The controller 51 may be configured to control the respective components of the plasma processing apparatus 1 to perform the various processes to be described herein below. The controller 51 may include, for example, a computer. The computer may include, for example, a processor (central processing unit; CPU) 511, a storage unit 512, and a communication interface 513. The processor 511 may be configured to perform various control operations based on programs stored in the storage unit 512. The storage unit 512 may include a RAM (random access memory), a ROM (read only memory), an HDD (hard disk drive), an SSD (solid state drive), or a combination thereof. The communication interface 513 may communicate with another apparatus such as another plasma processing apparatus 1 via a communication line such as a LAN (local area network).

Next, the flow of the operation when the plasma processing apparatus 1 according to the embodiment measures the ion energy during a plasma processing will be briefly described. The inorganic EL substrate W2 held on a transfer arm is carried into the plasma processing chamber 10 from the gate valve 10b, and placed on the electrostatic chuck 112.

The gas supply 20 introduces a processing gas used for generating plasma into the plasma processing chamber 10 at a predetermined flow rate and a predetermined flow rate ratio. The exhaust system 40 reduces the pressure in the plasma processing chamber 10 to a set value. The RF power supply 30 supplies the radio-frequency powers of the first RF signal and the second RF signal each having a predetermined power from the two RF generators 31a and 31b, respectively, to the lower electrode 111. The processing gas introduced from the upper-electrode shower head 12 into the plasma processing space 10s in a shower form is turned into plasma by the radio-frequency power of the first RF signal of the RF power supply 30. As a result, plasma is generated in the plasma processing space 10s. The plasma contains radicals and ions of the processing gas. The positive ions in the plasma are accelerated toward the support 11 by the electric field of the radio-frequency power generated by the radio-frequency power of the second RF signal. In the plasma processing, the accelerated positive ions are incident on the substrate W1 or the inorganic EL substrate W2 stacked on the support 11 so that the etching is implemented.

FIG. 3 is a view schematically illustrating an electrical state of the surface of the substrate W according to the embodiment. When the first RF signal and the second RF signal are applied to the lower electrode, a plasma sheath is formed near the substrate W. The substrate W is brought into a negative potential with respect to the plasma by the self-bias. The magnitude of the negative potential changes according to the powers of the first RF signal and the second RF signal applied to the lower electrode. An electric field is generated in the sheath by the negative self-bias applied to the substrate W, and the positive ions are accelerated toward the substrate by the electric field. The accelerated positive ions 80 are incident on the substrate W so that the substrate W is etched.

For the inorganic EL substrate W2, an electric field is generated by a sheath voltage near the substrate by the radio-frequency powers of the first RF signal and the second RF signal supplied from the RF generators 31a and 31b to the lower electrode 111. In the inorganic EL substrate W2, the light emitting layer 71 emits light according to the generated electric field. The first RF signal is, for example, 40 MHz. The second RF signal is, for example, 40 kHz. The electric field of the inorganic EL substrate W2 fluctuates in a waveform in which the two radio-frequency powers of the first RF signal and the second RF signal are superimposed. Since the radio-frequency power of the first RF signal is superimposed on the radio-frequency power of the second RF signal, the electric field of the inorganic EL substrate W2 greatly fluctuates in accordance with the period of the second RF signal of the relatively low frequency. That is, the light emission intensity of the light emitting layer 71 of the inorganic EL substrate W2 greatly fluctuates according to the electric field intensity of the relatively low frequency applied to the inorganic EL substrate W2.

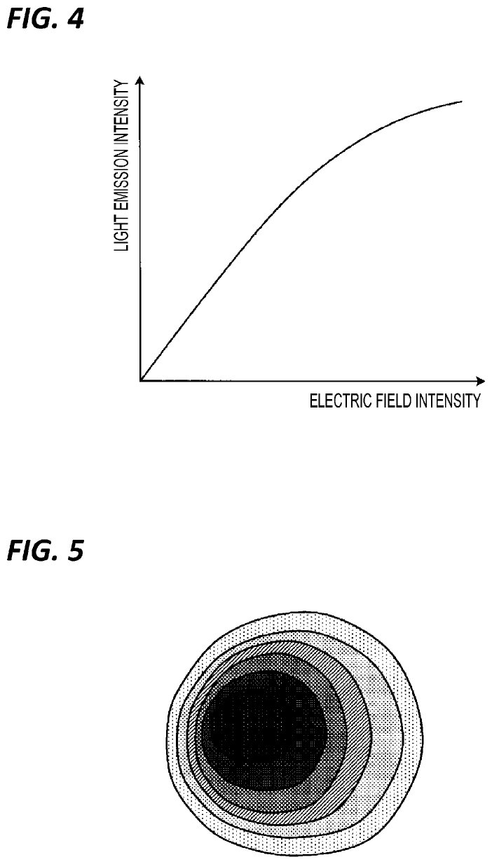

FIG. 4 is a view illustrating an example of the relationship between the light emission intensity of the light emitting layer 71 and the electric field intensity according to the embodiment. The horizontal axis of FIG. 4 represents the electric field intensity (the intensity of the electric field) applied to the light emitting layer 71. The vertical axis of FIG. 4 represents the light emission intensity (the intensity of the light emission) of the light emitting layer 71. The light emission intensity of the light emitting layer 71 tends to increase as the electric field becomes intense. Accordingly, by measuring the light emission intensity of the light emitting layer 71 of the inorganic EL substrate W2, the intensity of the electric field generated on the inorganic EL substrate W2 may be measured.

The spectroscope 62 measures the wavelength and the emission intensity of the light emitted by the inorganic EL substrate W2 through the transmission window 60. The spectroscope 62 outputs measurement data of the measured wavelength and light emission intensity to the controller 51.

The controller 51 measures the ion energy from the measurement result obtained from the spectroscope 62. For example, the controller 51 indirectly measures the ion energy by measuring the intensity of the electric field generated on the inorganic EL substrate W2 from the measurement data input from the spectroscope 62. The controller 51 moves the plurality of lenses 63 by the driving mechanism 64 so as to change the position of the focal point within the light emitting area of the inorganic EL substrate W2 and comprehensively scan the light emitting area, thereby measuring the light emission of the inorganic EL substrate W2 by the spectroscope 62. The spectroscope 62 outputs measurement data for each moved position to the controller 51. The controller 51 measures the intensity of the electric field generated on the inorganic EL substrate W2 from the measurement data input from the spectroscope 62. For example, the controller 51 stores data that represents the correspondence relationship between the wavelength/the light emission intensity of the inorganic EL substrate W2 and the electric field intensity, in the storage unit 512. Based on the data stored in the storage unit 512, the controller 51 measures the intensity of the electric field generated on the inorganic EL substrate W2 from the measurement data. As an example, the controller 51 stores data that represents the correspondence relationship between the light emission intensity and the electric field intensity, for a specific wavelength in which the light emission intensity of the inorganic EL substrate W2 changes according to the electric field intensity, in the storage unit 512. The controller 51 obtains the light emission intensity of the specific wavelength from the input measurement data. The controller 51 obtains the electric field intensity that corresponds to the obtained light emission intensity, from the data stored in the storage unit 512. From the measurement data, the controller 51 obtains the intensity of the electric field generated on the inorganic EL substrate W2 for each portion of the light emitting area of the inorganic EL substrate W2. The controller 51 measures the ion energy from the obtained electric field intensity.

As illustrated in FIG. 3, the positive ions 80 in the plasma are accelerated by the electric field in the sheath. Thus, the ion energy of the ions 80 is related to the electric field in the sheath, and the sheath voltage near the substrate may be measured from the intensity of the electric field generated on the inorganic EL substrate W2. Thus, by obtaining the electric field intensity of the inorganic EL substrate W2, the sheath voltage or the ion energy near the substrate may be measured. For example, the controller 51 stores the data that represents the correspondence relationship between the electric field intensity of the inorganic EL substrate W2 and the ion energy, in the storage unit 512. Based on the data stored in the storage unit 512, the controller 51 measures the ion energy from the obtained electric field intensity. From the electric field intensity of each portion within the light emitting region of the inorganic EL substrate W2, the controller 51 measures the ion energy for each portion within the light emitting area. As a result, the energy distribution may be measured. The controller 51 may store data that represents the correspondence relationship between the light emission intensity and the sheath voltage or the ion energy, and may obtain the sheath voltage or the ion energy that corresponds to the light emission intensity from the stored data.

Here, in the manufacture of semiconductor devices, the aspect ratio of a pattern formed has increased. For example, in the manufacture of a 3D NAND, an etching for a contact hole with a high aspect ratio is required. The etching for a contact hole with a high aspect ratio requires relatively high ion energy. The ion energy of ions greatly affects the progress of a process. In order to measure the ion energy in the plasma, for example, there is a method of directly measuring the potential using the measurement substrate as in Japanese Patent Laid-Open Publication No. 2014-513390. However, no wires exist in the substrate W1 which is an actual target of the plasma processing. Thus, the ion energy measured using the measurement substrate having the wires may be different from the ion energy measured by the substrate W1 having no wires. Further, when the potential of the measurement substrate becomes a relatively high voltage of −1,000 V or more, a short circuit or an abnormal discharge may occur, and thus, it may be difficult to perform the measurement while drawing the wires around from the measurement substrate.

The plasma processing apparatus 1 according to the embodiment prepares the inorganic EL substrate W2 in which the light emitting layer 71 and the dielectric layer 70 are stacked on the silicon substrate 72, similar to the substrate W1 which is a target of the plasma processing. The plasma processing apparatus 1 places the prepared inorganic EL substrate W2 on the support 11 inside the plasma processing chamber 10, and measures the emission intensity of the light emitted from the inorganic EL substrate W2 when plasma is generated. In this way, the plasma processing apparatus 1 may measure the ion energy of the substrate W1 which is a target of the plasma processing. The plasma processing apparatus 1 according to the embodiment may measure the ion energy of the substrate W1 which is an actual target of the plasma processing, in real time. Further, the plasma processing apparatus 1 according to the embodiment may measure the ion energy even when the potential of the substrate W1 becomes a relatively high voltage of −1,000 V or more.

FIG. 5 is a view illustrating an example of the distribution of the ion energy according to the embodiment. FIG. 5 represents the distribution of the ion energy in which an area with relatively high ion energy is represented in a relatively dark pattern. In this way, the plasma processing apparatus 1 according to the embodiment may measure the in-plane distribution of the ion energy in the plasma processing space 10s.

### Flow of Plasma Measurement

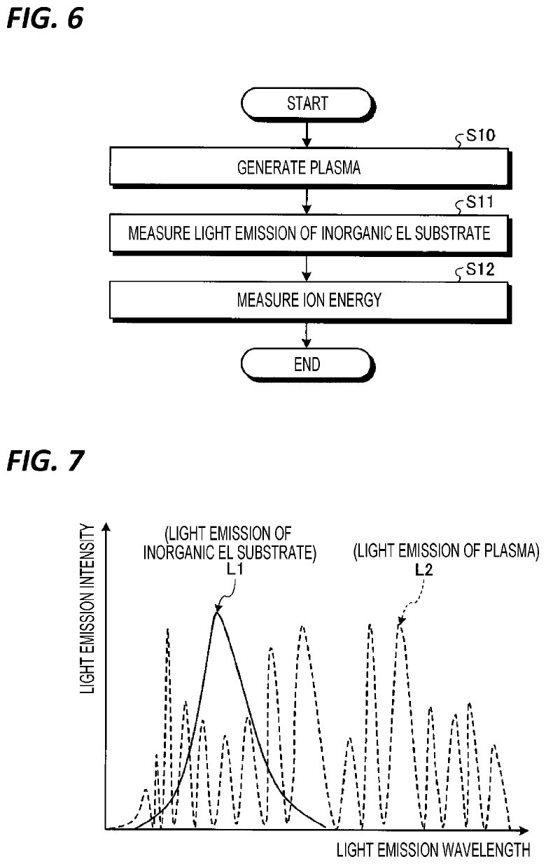

Next, descriptions will be made on the flow of the plasma measuring method that is performed by the plasma processing apparatus 1 according to the embodiment. FIG. 6 is a flowchart illustrating an example of the flow of the plasma measuring method according to the embodiment.

The controller 51 controls each component of the plasma processing apparatus 1 to generate plasma in the plasma processing chamber 10 (step S10). For example, the controller 51 controls the gas supply 20 to introduce the processing gas used for generating plasma into the plasma processing chamber 10 at a predetermined flow rate and a predetermined flow rate ratio. Further, the controller 51 controls the exhaust system 40 to reduce the pressure in the plasma processing chamber 10 to a set value. Further, the controller 51 controls the RF power supply 30 to supply the radio-frequency powers of the first RF signal and the second RF signal each having a predetermined power from the two RF generators 31a and 31b, respectively, to the lower electrode 111. As a result, plasma is generated in the plasma processing space 10s.

The controller 51 controls the spectroscope 62 and the driving mechanism 64, and measures the light emission of the plasma through the transmission window 60 by the spectroscope 62 (step S1). For example, the controller 51 moves the plurality of lenses 63 by the driving mechanism 64 so as to change the position of the focal point within the light emitting area of the inorganic EL substrate W2 and comprehensively scan the light emitting area, thereby measuring the light emission of the plasma by the spectroscope 62. The spectroscope 62 outputs measurement data of the measured wavelength and light emission intensity to the controller 51.

The controller 51 measures the ion energy from the measurement data input from the spectroscope 62 (step S12), and ends the process. For example, the controller 51 obtains the intensity of the electric field generated on the inorganic EL substrate W2 from the measurement data, for each position within the light emitting area of the inorganic EL substrate W2. The controller 51 measures the ion energy from the obtained electric field intensity.

In the plasma processing apparatus 1 according to the embodiment, the spectroscope 62 measures not only the light emitted by the inorganic EL substrate W2 but also the light emitted by the plasma. FIG. 7 is a view illustrating an example of the measured light emission intensity according to the embodiment. FIG. 7 represents a distribution L1 of the light emission intensity for each light emission wavelength by the light emission of the inorganic EL substrate W2, and a distribution L2 of the light emission intensity for each light emission wavelength by the light emission of the plasma. The spectroscope 62 measures not only the light emitted from the inorganic EL substrate W2 but also the light emitted from the plasma. Accordingly, the plasma processing apparatus 1 according to the embodiment may be configured as described below.

The plasma processing apparatus 1 according to the embodiment individually measures the light emission for each of a state where the inorganic EL substrate W2 is not placed in the plasma processing chamber 10 and a state where the inorganic EL substrate W2 is placed in the plasma processing chamber 10. For example, the plasma processing apparatus 1 generates plasma in a state where the normal substrate W1 which is a target of the plasma processing is placed on the support 11, and the spectroscope 62 measures the light emission of the plasma in a state where the inorganic EL substrate W2 is not placed. In the plasma processing apparatus 1, the substrate W1 and the inorganic EL substrate W2 are exchanged by a transfer arm such that the inorganic EL substrate W2 is placed on the support 11. Then, the plasma processing apparatus 1 generates plasma in a state where the inorganic EL substrate W2 is placed on the support 11, and the spectroscope 62 measures the light emission of the plasma and the inorganic EL substrate W2 in a state where the inorganic EL substrate W2 is placed. The controller 51 compares measurement data obtained in a state where the inorganic EL substrate W2 is not placed, with measurement data obtained in a state where the inorganic EL substrate W2 is placed. From the comparison result, the controller 51 obtains the intensity of the electric field generated on the inorganic EL substrate W2. By calculating the difference between the measurement data obtained in a state where the inorganic EL substrate W2 is placed and the measurement data obtained in a state where the inorganic EL substrate W2 is not placed, data that corresponds to the light emission of the inorganic EL substrate W2 may be obtained. The controller 51 obtains data of the difference between the measurement data obtained in a state where the inorganic EL substrate W2 is placed and the measurement data obtained in a state where the inorganic EL substrate W2 is not placed. From the difference data, the controller 51 obtains the intensity of the electric field generated on the inorganic EL substrate W2. Then, the controller 51 measures the ion energy from the obtained electric field intensity. For example, the controller 51 stores data that represents the correspondence relationship between the electric field intensity and the ion energy, in the storage unit 512. Based on the data stored in the storage unit 512, the controller 51 measures the ion energy from the obtained electric field intensity.

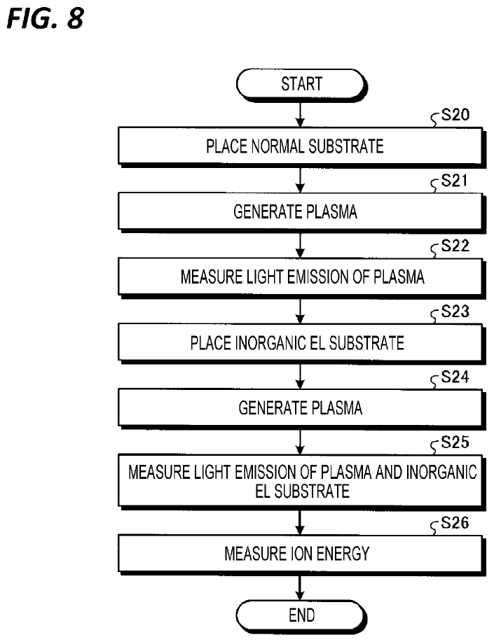

In this case, the plasma processing apparatus 1 according to the embodiment performs, for example, the measurement of the plasma as described below. FIG. 8 is a flowchart illustrating another example of a process other than the flow of the plasma measuring method according to the embodiment.

In the plasma processing apparatus 1, the normal substrate W1 which is a target of the plasma processing is placed on the support 11 by a transfer arm (step S20).

The controller 51 controls each component of the plasma processing apparatus 1, and generates plasma in the plasma processing chamber 10 in a state where the substrate W1 is placed inside the plasma processing chamber 10 (a state where the inorganic EL substrate W2 is not placed) (step S21). For example, the controller 51 controls the gas supply 20 to introduce the processing gas used for generating plasma into the plasma processing chamber 10 at a predetermined flow rate and a predetermined flow rate ratio. Further, the controller 51 controls the exhaust system 40 to reduce the pressure in the plasma processing chamber 10 to a set value. Further, the controller 51 controls the RF power supply 30 to supply the radio-frequency powers of the first RF signal and the second RF signal each having a predetermined power from the two RF generators 31a and 31b, respectively, to the lower electrode 111. As a result, plasma is generated in the plasma processing space 10s.

The controller 51 controls the spectroscope 62 and the driving mechanism 64, and measures the light emission of the plasma through the transmission window 60 by the spectroscope 62 (step S22). For example, the controller 51 moves the plurality of lenses 63 by the driving mechanism 64 so as to change the position of the focal point within the light emitting area of the inorganic EL substrate W2 and comprehensively scan the light emitting area, thereby measuring the light emission of the plasma by the spectroscope 62. The spectroscope 62 outputs measurement data of the measured wavelength and light emission intensity to the controller 51.

In the plasma processing apparatus 1, the inorganic EL substrate W2 is placed inside the plasma processing chamber 10 (step S23). For example, in the plasma processing apparatus 1, the substrate W1 is taken out from the support 11, and the inorganic EL substrate W2 is placed on the support 11, by a transfer arm.

The controller 51 controls each component of the plasma processing apparatus 1, and generates plasma in the plasma processing chamber 10 in a state where the inorganic EL substrate W2 is placed inside the plasma processing chamber 10 (step S24). The conditions for generating plasma may be the same as those in step S21 described above. For example, the controller 51 generates plasma with the same gas, the same pressure, the same frequency, and the same power as those in step S21.

The controller 51 controls the spectroscope 62 and the driving mechanism 64, and measures the light emission of the inorganic EL substrate W2 through the transmission window 60 by the spectroscope 62 (step S25). For example, the controller 51 moves the plurality of lenses 63 by the driving mechanism 64 so as to change the position of the focal point within the light emitting area of the inorganic EL substrate W2 and comprehensively scan the light emitting area, thereby measuring the light emission of the light emitting area by the spectroscope 62. The spectroscope 62 outputs measurement data of the measured wavelength and light emission intensity to the controller 51.

The controller 51 compares the measurement data obtained in a state where the inorganic EL substrate W2 is not placed, with the measurement data obtained in a state where the inorganic EL substrate W2 is placed, measures the ion energy from the comparison result (step S26), and ends the process. For example, the controller 51 obtains data of the difference between the measurement data obtained in a state where the inorganic EL substrate W2 is placed and the measurement data obtained in a state where the inorganic EL substrate W2 is not placed, for each position within the light emitting area of the inorganic EL substrate W2. From the obtained difference data, the controller 51 obtains data that corresponds to the light emission of the inorganic EL substrate W2, for each position within the light emitting area. From the data that corresponds to the light emission, the controller 51 obtains the intensity of the electric field generated on the inorganic EL substrate W2, for each position within the light emitting area. The controller 51 measures the ion energy from the obtained electric field intensity.

When the data of the light emission intensity of the plasma is separately obtained, the controller 51 may obtain data of the difference between the measurement data obtained in a state where the inorganic EL substrate W2 is placed and the data of the light emission intensity of the plasma, so as to obtain the electric field intensity. When the amount of the light emission of the plasma is relatively small, the controller 51 may obtain the electric field intensity from the measurement data obtained in a state where the inorganic EL substrate W2 is placed.

As described above, the plasma processing apparatus 1 according to the embodiment includes the plasma processing chamber 10, the support 11 (a stage), the RF power supply 30 (a plasma generation source), the inorganic EL substrate W2, the transmission window 60, the spectroscope 62, and the controller 51. The support 11 is provided inside the plasma processing chamber 10. The RF power supply 30 generates plasma in the plasma processing chamber 10. The inorganic EL substrate W2 is placed on the support 11, and emits light when an electric field is applied. The transmission window 60 is provided in the plasma processing chamber 10, and transmits light. The spectroscope 62 is disposed outside the plasma processing chamber 10, and measures the light emission of the inorganic EL substrate W2 through the transmission window 60. The controller 51 measures the ion energy from the measurement result obtained from the spectroscope 62. As a result, the plasma processing apparatus 1 may measure the ion energy of the plasma processing.

The transmission window 60 is provided in the side wall of the plasma processing chamber 10. The lenses 63 are arranged between the transmission window 60 and the spectroscope 62, and focus on a portion of the light emitting area of the inorganic EL substrate W2. As a result, the plasma processing apparatus 1 may measure the ion energy at the position on which the lenses 63 focus within the light emitting area of the inorganic EL substrate W2.

The driving mechanism 64 drives any one or both of the lenses 63 and the spectroscope 62 such that the position of the focal point moves within the light emitting area. As a result, by driving the lenses 63 by the driving mechanism 64, the plasma processing apparatus 1 may measure the ion energy for each portion within the light emitting area and may measure the energy distribution.

The inorganic EL substrate W2 includes the dielectric layer 70, the light emitting layer 71, and the silicon substrate 72 that supports the dielectric layer 70 and the light emitting layer 71. The light emitting layer 71 includes any one of SrS:Ce, ZnS:Tm, ZnS:Mo, SnS:Tm, SnS:Sm, CaS:Eu, and CaS:Se. As a result, the light emitting layer 71 of the inorganic EL substrate W2 emits light when an electric field is applied.

While the embodiments have been described, the embodiments are merely examples and should not be construed as limiting the present disclosure. The foregoing embodiments may be actually implemented in various ways. Further, the foregoing embodiments may be omitted, replaced, or changed in various forms without departing from the scope and gist of the claims.

For example, in the above-described embodiments, one or both of the lenses 63 and the spectroscope 62 are driven by the driving mechanism 64 so as to move the position of the focal point. However, the present disclosure is not limited thereto. Any other configuration may be used as long as the position of the focal point is movable. For example, the position of the focal point may be moved by driving an optical component such as a lens or a mirror. Further, for example, a plurality of lenses may be arranged to have different optical axes, and light collected by the plurality of lenses may be supplied for the scanning to the spectroscope 62 through an optical fiber.

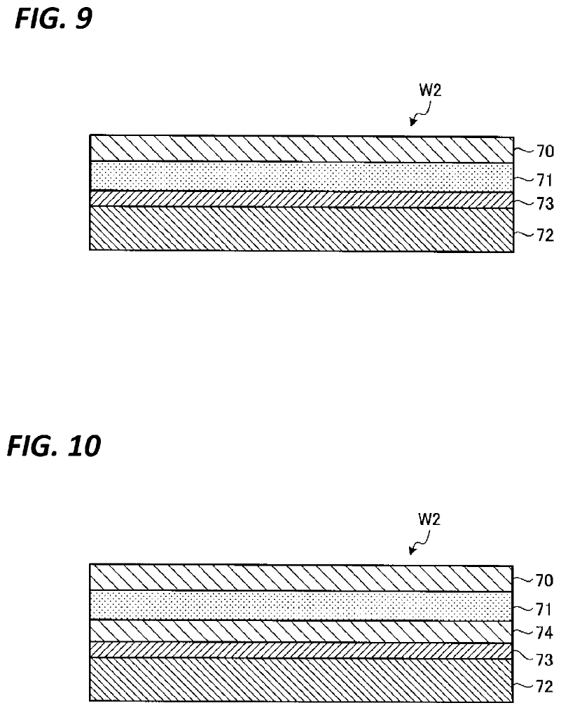

The inorganic EL substrate W2 may include other layers. FIG. 9 is a schematic cross-sectional view illustrating another example of the configuration of the inorganic EL substrate W2 according to the embodiment. In the inorganic EL substrate W2 illustrated in FIG. 9, an antireflection film 73 is formed between the light emitting layer 71 and the silicon substrate 72, in addition to the dielectric layer 70 and the light emitting layer 71. The dielectric layer 70 has a thickness of hundreds of nm (e.g., 650 nm) and is formed of, for example, SiO₂. The light emitting layer 71 has a thickness of tens of nm (e.g., 60 nm) and is formed of, for example, ZnS:Mo. The antireflection film 73 has a thickness of tens to hundreds of nm (e.g., 100 nm) and is formed of, for example, a metal material such as aluminum. The antireflection film 73 reflects the light of the light emitting layer 71. As a result, the inorganic EL substrate W2 emits more intense light at the side close to the dielectric layer 70. FIG. 10 is a schematic cross-sectional view illustrating yet another example of the configuration of the inorganic EL substrate W2 according to the embodiment. In the inorganic EL substrate W2 illustrated in FIG. 10, an antireflection film 73 and a dielectric layer 74 are formed between the light emitting layer 71 and the silicon substrate 72, in addition to the dielectric layer 70 and the light emitting layer 71. The antireflection film 73 is formed on the silicon substrate 72. The dielectric layer 74 is formed on the antireflection film 73. The dielectric layer 70 has a thickness of hundreds of nm (e.g., 650 nm) and is formed of, for example, SiO₂. The light emitting layer 71 has a thickness of tends of nm (e.g., 60 nm) and is formed of, for example, ZnS:Mo. The dielectric layer 74 has a thickness of hundreds of nm (e.g., 650 nm) and is formed of, for example, SiO₂. The antireflection film 73 has a thickness of tens to hundreds of nm (e.g., 100 nm) and is formed of, for example, a metal material such as aluminum. The antireflection film 73 reflects the light of the light emitting layer 71. In this case as well, the inorganic EL substrate W2 emits more intense light at the side close to the dielectric layer 70.

The technique of the present disclosure may be adopted for any plasma processing apparatus. For example, the plasma processing apparatus 1 is any type of plasma processing apparatus such as an inductively coupled plasma (ICP) type processing apparatus or a plasma processing apparatus for exciting a gas by surface waves such as microwaves.

In the above-described embodiments, a plasma etching apparatus has been described as an example of the plasma processing apparatus 1. However, the present disclosure is not limited thereto. The technique of the present disclosure may be applied to, for example, a film forming apparatus or a modifying apparatus that uses plasma.

In the above-described embodiments, a semiconductor wafer has been described as an example of the substrate. However, the present disclosure is not limited thereto. The substrate may be another substrate such as a glass substrate.

According to the present disclosure, the ion energy of a plasma processing may be measured.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma measuring apparatus comprising:
a chamber;
a stage provided inside the chamber;
a plasma generation source configured to generate plasma in the chamber;
an inorganic electroluminescence (EL) substrate placed on the stage and configured to emit light when an electric field is applied;
a transmission window provided in the chamber and configured to transmit light;
a spectroscope disposed outside the chamber and configured to measure a light emission of the inorganic EL substrate through the transmission window; and
a controller configured to measure an ion energy from a result of the measurement by the spectroscope.

2. The plasma measuring apparatus according to claim 1, wherein the transmission window is provided in a side wall of the chamber, and
the plasma measuring apparatus further comprises a lens disposed between the transmission window and the spectroscope and configured to focus on a portion of a light emitting area of the inorganic EL substrate.

3. The plasma measuring apparatus according to claim 2, further comprising:
a driver configured to drive any one or both of the lens and the spectroscope to move a position of a focal point within the light emitting area.

4. The plasma measuring apparatus according to claim 1, wherein the inorganic EL substrate includes a dielectric layer, a light emitting layer, and a silicon substrate that supports the dielectric layer and the light emitting layer.

5. The plasma measuring apparatus according to claim 4, wherein the light emitting layer includes any one of SrS:Ce, ZnS:Tm, ZnS:Mo, SnS:Tm, SnS:Sm, CaS:Eu, and CaS:Se.

6. A plasma measuring method comprising:
generating plasma in a chamber provided therein with a stage configured to place an inorganic EL substrate that emits light when an electric field is applied, and a transmission window configured to transmit light;
measuring a light emission of the inorganic EL substrate through the transmission window by a spectroscope disposed outside the chamber; and
measuring an ion energy from a result obtained in the measuring the light emission.

7. The plasma measuring method according to claim 6, further comprising:
placing the inorganic EL substrate on the stage,
wherein the generating the plasma includes generating a first plasma in the chamber in a state where the inorganic EL substrate is not placed in the chamber, and generating a second plasma in the chamber in a state where the inorganic EL substrate is placed in the chamber,
the measuring the light emission includes measuring the light emission of the inorganic EL substrate through the transmission window when the first plasma is generated, and measuring the light emission of the inorganic EL substrate through the transmission window when the second plasma is generated, and
the measuring the ion energy compares first data measured when the first plasma is generated with second data measured when the second plasma is generated, obtains an intensity of an electric field generated on the inorganic EL substrate from a result of the comparison, and measures the ion energy from the obtained intensity of the electric field.

8. The plasma measuring method according to claim 6, wherein the inorganic EL substrate includes a dielectric layer, a light emitting layer, and a silicon substrate that supports the dielectric layer and the light emitting layer.

9. The plasma measuring method according to claim 7, wherein in the generating the first plasma, plasma is generated in a state where a substrate other than the inorganic EL substrate is placed.

10. The plasma measuring method according to claim 7, wherein the first plasma and the second plasma are generated from a same gas.

11. The plasma measuring method according to claim 10, wherein the measuring the light emission measures the light emission of the inorganic EL substrate for each of a case where the first plasma is generated and a case where the second plasma is generated, by driving any one or both of a lens disposed between the transmission window and the spectroscope and configured to focus on a portion of a light emitting area of the inorganic EL substrate, and the spectroscope, and
the measuring the ion energy compares the first data and the second data that are measured at a same position within the light emitting area with each other, and measures the ion energy for each position from a result of the comparison.
